(19) United States
(12) Patent Application Publication
(10) Pub. No.: US 2010/0035376 A1
(43) Pub. Date: Feb. 11, 2010

(54) METHOD OF LOCALLY CRYSTALLIZING ORGANIC THIN FILM AND METHOD OF FABRICATING ORGANIC THIN FILM TRANSISTOR USING THE SAME

(75) Inventors: Yong Young Noh, Daejeon (KR); Kang Jun Baeg, Gwangju (KR); In Kyu You, Daejeon (KR); Jae Bon Koo, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/424,760

(22) Filed: Apr. 16, 2009

(30) Foreign Application Priority Data
Aug. 11, 2008 (KR) 10-2008-0078593

(51) Int. Cl. H01L 51/40

(52) U.S. Cl. 438/99; 257/E51.005

(57) ABSTRACT

A method of partially crystallizing an organic thin film and a method of fabricating an organic thin film transistor (OTFT) are provided. An organic thin film used as an active layer of an OTFT is partially coated with an organic solvent by direct graphic art printing or partially annealed by laser beam irradiation, thereby local improving the crystallinity of the organic thin film. The charge mobility of the OTFT can be improved and crosstalk between devices can be reduced without additional patterning the organic thin film.

### CROSS-REFERENCE TO RELATED APPLICATION

This application claims priority to and the benefit of Korean Patent Application No. 10-2008-0078593, filed Aug. 11, 2008, the disclosure of which is incorporated herein by reference in its entirety.

### BACKGROUND

1. Field of the Invention

The present invention relates to a method of locally crystallizing an organic thin film and a method of fabricating an organic thin film transistor (OTFT) using the same, and more specifically, to a method of locally improving the crystallinity of an organic thin film used as an active layer of an OTFT by local deposition of an organic solvent by direct graphic art printing or local annealing the organic thin film by laser beam irradiation.

2. Discussion of Related Art

An organic thin film transistor (OTFT), which is a device using an active layer formed of an organic material, has been proposed and studied due to their potential for application of low cost electronics. In recent years, a vast amount of research has been conducted on various uses of the OTFT as a driving device of a low-quality display device, a radio-frequency identification (RFID), or a smart card.

Although the OTFT is structurally about the same as a silicon thin film transistor (TFT), it employs an organic thin film as an active layer instead of a silicon thin film.

In an OTFT, an organic thin film is typically formed using a vacuum evaporation process or a solution deposition process. The vacuum evaporation process involves applying heat to an organic semiconductor material in vacuum to deposit the organic semiconductor material in a sublimated state. The solution deposition process involves dissolving an organic semiconductor material in an organic solvent and depositing the dissolved organic semiconductor material using a printing coating technique or a spin coating technique.

Compared with the vacuum evaporation process, the solution deposition process is a simple fabrication process requiring no expensive vacuum fabrication apparatus, and thus is advantageous in terms of fabrication costs. However, since an organic thin film formed using the solution deposition process shows a lower crystallinity than an organic thin film formed using the vacuum evaporation process, it has charge mobility typically about 10 times lower than the organic thin film formed using the vacuum evaporation process. In particular, since organic semiconductor materials capable of the solution deposition process are mostly high-molecular-weight polymers, it is difficult to expect that the crystallinity of an organic semiconductor material will be improved by active movement of molecules in a solution.

Therefore, research has been focusing on various methods for increasing charge mobility by improving the crystallinity of an organic thin film obtained using a solution deposition process.

In one approach, a method of improving the crystallinity of an organic thin film by replacing a conventional organic semiconductor material having an irregular structure (i.e., regiorandom poly(3-alkylthiophene)) with a material having regular molecular arrangement (i.e., regioregular poly(3-alkylthiophene)) has been disclosed. However, since this method is limited to specific molecular structures, it cannot be used for a wide range of applications.

In another approach, a method of improving the crystallinity of an organic thin film by forming a self-assembled monolayer having a low surface energy on a gate insulating layer under the organic thin film has been disclosed. However, the self-assembled monolayer may be formed only on a specific substrate and applied only to a bottom-gate structure in which the organic thin film is formed over the gate insulating layer.

In still another approach, a method of attempting to improve the crystallinity of an organic thin film involves exposing the organic thin film formed using a solution deposition process to the vapor of an organic solvent to change the organic thin film into a soft phase, thereby increasing the activity of molecules. In this method, however, a process speed is slow and it is necessary to manipulate the vapor of the organic solvent which is harmful to humans. In addition, it is difficult to obtain uniform device performance.

Furthermore, when the crystallinity of the entire organic thin film is improved using the above-described methods, the electrical conductivity of the organic thin film increases so that crosstalk between adjacent devices may occur without additional patterning of the organic thin film, and an off-state leakage current may increase.

### SUMMARY OF THE INVENTION

The present invention is directed to a method of local improving the crystallinity of an organic thin film formed using a solution deposition process.

Also, the present invention is directed to a method of fabricating an organic thin film transistor (OTFT) using an organic thin film whose crystallinity is partially improved as an active layer, by which charge mobility of the OTFT can be increased and crosstalk between devices can be reduced without additional patterning of the organic thin film.

One aspect of the present invention provides a method of local crystallizing an organic thin film. The method includes: forming the organic thin film using an organic semiconductor material; changing a predetermined region of the organic thin film into a soft phase by local deposition of the predetermined region of the organic thin film with an organic solvent or irradiating the predetermined region of the organic thin film with laser beams; and improving the crystallinity of the predetermined region of the organic thin film by drying the soft-phase region of the organic thin film for a predetermined time.

Another aspect of the present invention provides a method of fabricating an OTFT. The method includes: sequentially forming a gate electrode, a gate insulating layer, source and drain electrodes, and an organic thin film on a substrate; changing a predetermined region of the organic thin film into a soft phase by local deposition of the predetermined region of the organic thin film with an organic solvent or irradiating the predetermined region of the organic thin film with laser beams; and improving the crystallinity of the predetermined region of the organic thin film by drying the soft-phase region of the organic thin film for a predetermined time.

When the predetermined region of the organic thin film is coated with the organic solvent, it may dissolve and change into a soft phase due to the organic solvent. As a result, organic molecules in the soft-phase organic thin film may move actively and be self-assembled due to van der Waals attraction therebetween, thereby improving the crystallinity of the predetermined region.

In this case, the organic solvent may be a material with a low evaporation rate so that it can take sufficient time for the organic molecules to move actively and be self-assembled in the region coated with the organic solvent.

The predetermined region of the organic thin film may be coated with the organic solvent using one direct printing technique selected from the group consisting of an inkjet printing technique, a screen printing technique, a gravure printing technique, an offset printing technique, and a flexography technique.

Meanwhile, when the predetermined region of the organic thin film is irradiated with the laser beams, it may be heated to a temperature at which a material constituting the organic thin film is crystallized. Thus, the predetermined region of the organic thin film may dissolve and change into a soft phase due to the laser beams. As a result, organic molecules in the soft-phase organic thin film may move actively and be self-assembled due to van der Waals attraction therebetween, thereby improving the crystallinity of the predetermined region.

In this case, in order to maximize the improvement of crystallinity, the organic thin film may be slowly cooled down to room temperature so that it can take sufficient time to self-assemble the organic molecules.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1 and 2 are diagrams for explaining a method of local crystallizing an organic thin film according to an exemplary embodiment of the present invention;

FIG. 3 shows light microscope (LM) images of a conventional TIPS-pentacene organic thin film and an organic thin film according to the present invention with locally improved crystallinity by partial coating with an organic solvent;

FIG. 4 is a cross-sectional view of an organic thin film transistor (OTFT) using an organic thin film with partially improved crystallinity by partial coating with an organic solvent as an active layer according to an exemplary embodiment of the present invention;

FIG. 5 is a cross-sectional view of an OTFT using an F8T2 organic thin film with locally improved crystallinity by partial annealing using laser beam irradiation as an active layer according to another exemplary embodiment of the present invention;

FIG. 6 shows a graph of gate voltage-drain current characteristics of the OTFT shown in FIG. 5 and a graph of drain voltage-drain current characteristics relative to a gate voltage in the OTFT shown in FIG. 5;

FIG. 7 is a diagram of a complementary metal oxide semiconductor (CMOS) inverter using an OTFT fabricated according to an exemplary embodiment of the present invention; and

FIG. 8 is a cross-sectional view of an OTFT fabricated according to an exemplary embodiment of the present invention, which is used as each of a switching transistor and a driving transistor of an organic light emitting diode (OLED).

### DETAILED DESCRIPTION OF EMBODIMENTS

The present invention will be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to one skilled in the art.

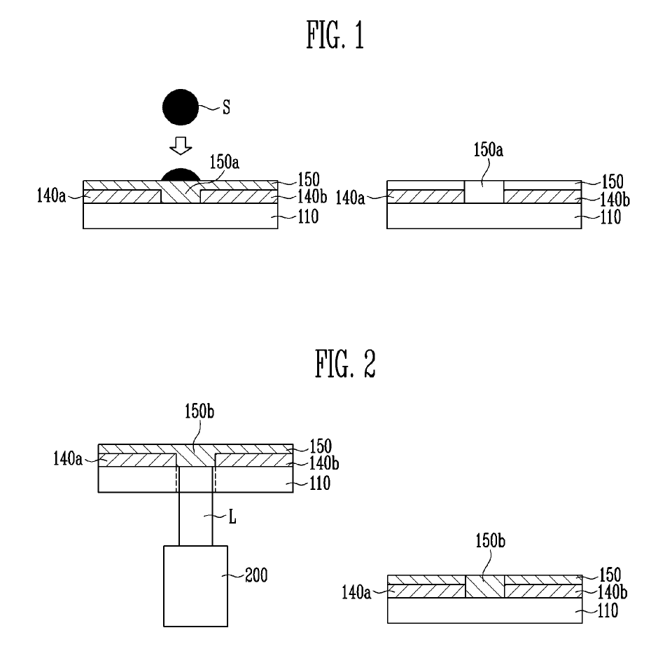

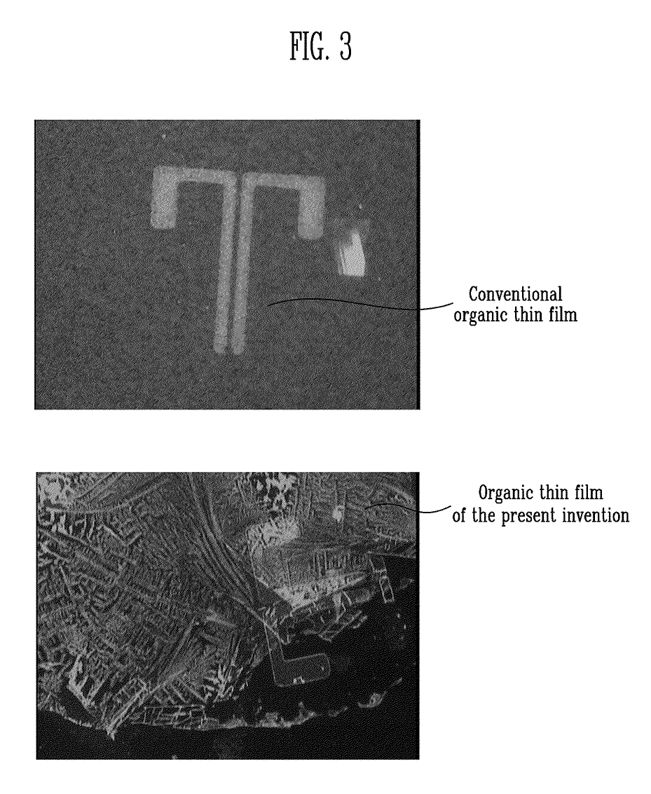

FIGS. 1 and 2 are diagrams for explaining a method of partially crystallizing an organic thin film according to an exemplary embodiment of the present invention.

First, referring to FIG. 1, the crystallinity of an organic thin film 150 formed using a solution deposition process may be partially improved by coating a desired predetermined region 150a of the organic thin film 150 formed on a substrate 10 with an organic solvent S and gradually evaporating the organic solvent S. As a result, molecules of the organic thin film 150 move more actively in a self-assembled manner only in the predetermined region 150a coated with the organic solvent S, thereby partially improving the crystallinity of the organic thin film 150.

In this case, the organic solvent S may be coated on the organic thin film 150 using a direct printing technique, such as an inkjet printing technique, a screen printing technique, a gravure printing technique, an offset printing technique, or a flexography technique. The predetermined region 150a whose crystallinity is improved may depend on the resolution of a direct printing technique.

Second, referring to FIG. 2, the crystallinity of an organic thin film 150 formed using a solution deposition process may be partially improved by irradiating only a bottom surface of a desired predetermined region 150b of the organic thin film 150 with laser beams L using a laser system 200 disposed below a substrate 110. As a result, only the predetermined region 150b irradiated with laser beams L is heated so that organic molecules move more actively in a self-assembled manner in the predetermined region 150b, thereby partially improving the crystallinity of the organic thin film 150.

In the present embodiment, the substrate 10 may be an n- or p-type doped silicon wafer, a glass substrate, or an organic substrate coated with a plastic film formed of, for example, polyethersulphone, polyacrylate, polyetherimide, polyimide, or polyethyeleneterepthalate.

The organic thin film 150 may be formed of any organic semiconductor material that can be deposited using a solution deposition technique. For example, the organic thin film 150 may be formed of one selected from the group consisting of polythiophene and derivatives thereof, thienothiophene and derivatives thereof, triisopropylsilyl (TIPS) pentacene and derivatives thereof, pentacene precursor and derivatives thereof, alpha-6-thiophene and derivatives thereof, polyfluorene and derivatives thereof, pentacene, tetracene, anthracene, perylene and derivatives thereof, rubrene and derivatives thereof, coronene and derivatives thereof, perylene tetracarboxylic diimide and derivatives thereof, polyparaphenylene vinylene (PPV) and derivatives thereof, poly(thiophene vinylene) (PTV) and derivatives thereof, alpha-5-thiophene oligothiophene and derivatives thereof, metal-containing and metal-free phthalocyanine and derivatives thereof, naphthalene tetracarboxylic acid diimide and derivatives thereof, and naphthalene tetracarboxylic acid dianhydride and derivatives thereof.

In the present invention, the organic thin film 150 formed using a solution deposition process is partially coated with the organic solvent or partially irradiated with laser beams L to partially improve the crystallinity of the organic thin film 150. The process of partially improving the organic thin film 150 will now be described in more detail.

Each and every organic semiconductor material has an extended π orbital in which several benzene rings are linked to each other, so that it has a strong van der Waals attraction. The van der Waals attraction is typically stronger than intermolecular repulsion caused in a π orbital when two molecules come close to each other. Accordingly, each organic semiconductor material retains a self-assembling characteristic to minimize an intermolecular distance by appropriate interaction between the strong van der Waals attraction and intermolecular repulsion.

However, in order to use the self-assembling characteristic of the organic semiconductor material, it is necessary to allow organic molecules to move freely. Therefore, when an organic thin film is changed into a soft phase by partially coating the organic thin film with an organic solvent or partially annealing the organic thin film with laser beam irradiation, organic semiconductor molecules become capable of moving more freely in a self-assembled manner in the organic thin film, thereby partially improving the crystallinity of the organic thin film.

### Embodiment 1

In the present embodiment, an organic thin film is formed of TIPS pentacene, and only a desired predetermined region of the TIPS pentacene organic thin film is coated with an organic solvent, for example, dichlorobenzene (DCB), trichlorobenzene (TCB), or 1-butanol using an inkjet printing technique, thereby partially improving the crystallinity of the TIPS pentacene organic thin film.

A method of partially crystallizing an organic thin film according to the present embodiment will now be described in more detail with reference to FIG. 1.

First, an organic semiconductor material, 1% by weight TIPS pentacene, is completely dissolved in one organic solvent selected from the group consisting of anisole, chlorobenzene, toluene, xylene, hexane, DCB, and dodecane to prepare a TIPS pentacene solution. Thereafter, the TIPS pentacene solution is coated on a substrate 110 using a spin coating process, a drop casting process, or an inkjet printing process, thereby forming a TIPS pentacene organic thin film 150.

In order to improve the uniformity of the TIPS pentacene organic thin film 150, the TIPS pentacene solution may be mixed with 50% by volume polystyrene (PS).

Thereafter, only a desired predetermined region 150a is coated with an organic solvent S, for example, DCB, TCB, or 1-butanol using an inkjet printing process.

Here, the following two points should be considered in selecting the organic solvent S.

First, the organic solvent S must be capable of dissolving the organic thin film 150 and being coated using a solution deposition process, such as an inkjet printing process.

Second, the organic solvent S must evaporate slowly. In other words, the organic solvent S must have a high boiling point and a low vapor pressure. The organic solvent S must evaporate slowly in order that molecules of the organic thin film 150 may move actively in a region coated with the organic solvent S and be self-assembled for a sufficient amount of time. Accordingly, it is preferable to select an organic solvent that has a boiling point of about 100° C. or higher and takes about 30 seconds to several minutes to completely evaporate.

Meanwhile, since the amount of the coated organic solvent S is also associated with its evaporation rate, when an excessively small amount of organic solvent S is coated, no matter how high the boiling point of the organic solvent S is, it is difficult to reduce its evaporation rate. Therefore, about 10 to 100 pl of organic solvent S may be coated using a typical industrial inkjet printer, for example, a jet drive from Microfab with a 50 μm-diameter nozzle.

When only the predetermined region 150a of the solid-phase organic thin film 150 is coated with the organic solvent S, the organic thin film 150 dissolves only in the region 150a coated with the organic solvent S and changes into a soft phase. As a result, organic molecules move actively in the soft-phase region 150a and are strongly self-assembled due to van der Waals attraction between the organic molecules, thereby partially improving the crystallinity of the organic thin film 150.

In this case, a self-assembled monolayer may be formed on the substrate 110 to reduce attraction between the organic molecules and the substrate 110. As a result, intermolecular attraction may be reinforced, thereby further facilitating self-assembly of the organic molecules.

The results obtained by partial coating with the organic solvent S are shown in FIG. 3.

FIG. 3 shows light microscope (LM) images of a conventional TIPS-pentacene organic thin film formed by a solution deposition process using a DCB solvent and an organic thin film according to the present invention with partially improved crystallinity by partial coating with an organic solvent.

Referring to FIG. 3, it can be observed that the crystallinity of a predetermined region of the organic thin film according to the present invention, which was coated with an organic solvent, was improved as compared with the conventional TIPS pentacene organic thin film formed using a spin coating process.

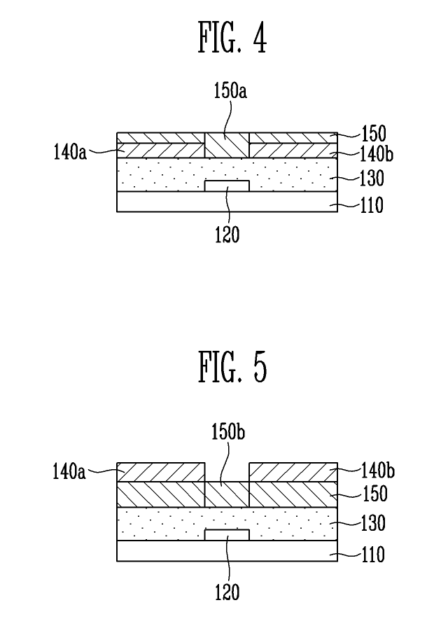

Meanwhile, an example of an organic thin film transistor (OTFT) using an organic thin film whose crystallinity is partially improved by coating with an organic solvent as an active layer is illustrated in FIG. 4.

FIG. 4 is a cross-sectional view of an OTFT using an organic thin film with partially improved crystallinity by partial coating with an organic solvent as an active layer according to an exemplary embodiment of the present invention.

Referring to FIG. 4, a gate electrode 120 and a gate insulating layer 130 may be formed on a substrate 110. Thereafter, a source electrode 140a and a drain electrode 140b may be formed and then an organic thin film 150 may be formed on the substrate having the source and drain electrodes 140a and 140b. An organic solvent S may be coated only on a predetermined region 150a of the organic thin film 150 to partially improve the crystallinity of the organic thin film 150. As a result, fabrication of a bottom-contact bottom-gate OTFT may be completed.

Although the present embodiment describes that TIPS pentacene is used as an organic semiconductor material constituting an organic thin film and DCB, TCB, or 1-butanol is used as an organic solvent for partially improving crystallinity, it is obvious that other materials may be used as the organic semiconductor material and the organic solvent.

### Embodiment 2

In the present embodiment, an organic thin film is formed of a material with a nematic liquid-crystal (LC) phase, for example, polythiophene derivatives, poly(2,5-bis(3-alkylthiophen-2yl)thieno [3,2-b]thiophene) (pBTTT), or poly(9,9-dioctylfuorene-co-bithiophene) (F8T2), only a desired predetermined region of the organic thin film is irradiated with laser beams, thereby partially improving the crystallinity of the organic thin film.

A method of partially crystallizing an organic thin film according to the present embodiment will now be described in more detail with reference to FIG. 2.

First, an organic thin film 150 is formed on a substrate 110 in the same manner as described in Embodiment 1.

Thereafter, only a bottom surface of a desired predetermined region 150b of the organic thin film 150 is irradiated with laser beams L until the predetermined region 150b is heated to a temperature at which a material having a nematic LC phase, which constitutes the organic thin film 150, is crystallized.

In this case, the intensity of laser beams L may be controlled. When the laser beams L are irradiated at an excessively high intensity, the organic thin film 150 may be abruptly degraded. Therefore, while the temperature of the organic thin film 150 is being measured using an infrared (IR) method, the intensity of the laser beams L may be controlled such that a portion of the substrate 110 to which the laser beams L are irradiated reaches a temperature of about 100° C. after about 10 to 20-minute irradiation.

When heated to a temperature at which the material having the nematic LC phase, which constitutes the organic thin film 150, is crystallized as described above, the predetermined region 150b of the organic thin film 150 may be changed from a solid phase to a soft phase. As a result, organic molecules move actively in the soft-phase region 150b and are strongly self-assembled due to van der Waals attraction between the organic molecules, thereby partially improving the crystallinity of the organic thin film 150.

Thereafter, the organic thin film 150, which is partially heated, is cooled down to room temperature using a natural drying process.

In this case, in order to maximize the improvement of crystallinity, the organic thin film 150 may be gradually cooled down at a rate of 0.01° C./sec so that it can take a sufficient time to self-assemble the organic molecules.

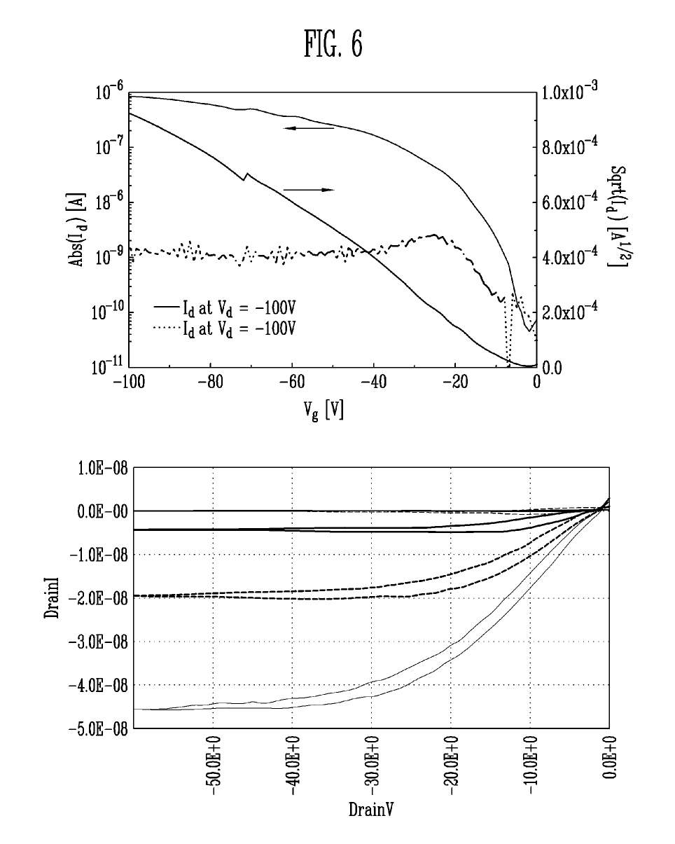

The structure and characteristics of an OTFT using an F8T2 organic thin film whose crystallinity is partially improved by partial annealing using laser beam irradiation as an active layer are illustrated in FIGS. 5 and 6.

FIG. 5 is a cross-sectional view of an OTFT using an F8T2 organic thin film with partially improved crystallinity by partial annealing using laser beam irradiation as an active layer according to the present embodiment, and FIG. 6 shows a graph of gate voltage-drain current characteristics of the OTFT shown in FIG. 5 and a graph of drain voltage-drain current characteristics relative to a gate voltage in the OTFT shown in FIG. 5.

Referring to FIG. 5, a gate electrode 120 and a gate insulating layer 130 may be formed on a substrate 110, and an organic thin film 150 may be formed on the substrate 110 having the gate electrode 120 and the gate insulating layer 130. Thereafter, laser beams L are irradiated only to a bottom surface of a desired predetermined region 150b of the organic thin film 150.

In this case, a region to which the laser beams L are irradiated may be controlled according to the size of the laser beams L. Preferably, a channel region of the OTFT may be uniformly irradiated with the laser beams L.

Finally, a source electrode 140a and a drain electrode 140b may be formed on the organic thin film 150. As a result, fabrication of a top-contact bottom-gate OTFT may be completed.

When the crystallinity of the organic thin film 150 is partially improved by partial annealing using laser beam irradiation as described above, it can be seen from FIG. 6 that the charge mobility and leakage current characteristics of the OTFT are improved.

As described above, since an organic thin film formed using a conventional solution deposition process has the same low crystallinity over the entire area, when the conventional organic thin film is used as an active layer of the OTFT, the OTFT has a low charge mobility and suffers from a leakage current and crosstalk between adjacent pixels. Accordingly, the conventional organic thin film needs to be patterned in order to solve the foregoing problems.

However, according to the present invention, the crystallinity of an organic thin film may be partially improved without patterning the organic thin film. Therefore, when the organic thin film whose crystallinity is partially improved is used as an active layer of an OTFT, the charge mobility of the OTFT can be enhanced and crosstalk between devices can be minimized.

Meanwhile, a method of partially crystallizing an organic thin film according to the present invention can be applied not only to OTFTs with various structures but also to inverters, switching and driving devices of display devices, RFIDs, and smart cards, which employ the OTFTs. This will now be described in more detail with reference to FIG. 7.

FIG. 7 is a diagram of a complementary metal oxide semiconductor (CMOS) inverter using an OTFT fabricated according to an exemplary embodiment of the present invention.

Referring to FIG. 7, fabrication of a CMOS inverter included forming a p-type organic thin film 150p and an n-type organic thin film 150n using a solution deposition process, such as a spin coating process. Thereafter, organic solvents Sp and Sn were partially coated on the p-type organic thin film 150p and the n-type organic thin film 150n, respectively, using an inkjet printing process, thereby partially improving the crystallinities of the p-type organic thin film 150p and the n-type organic thin film 150n at the same time.

That is, the organic thin films 150p and 150n whose crystallinities were partially improved were used as an active layer of an OTFT, and the CMOS inverter was fabricated using the OTFT.

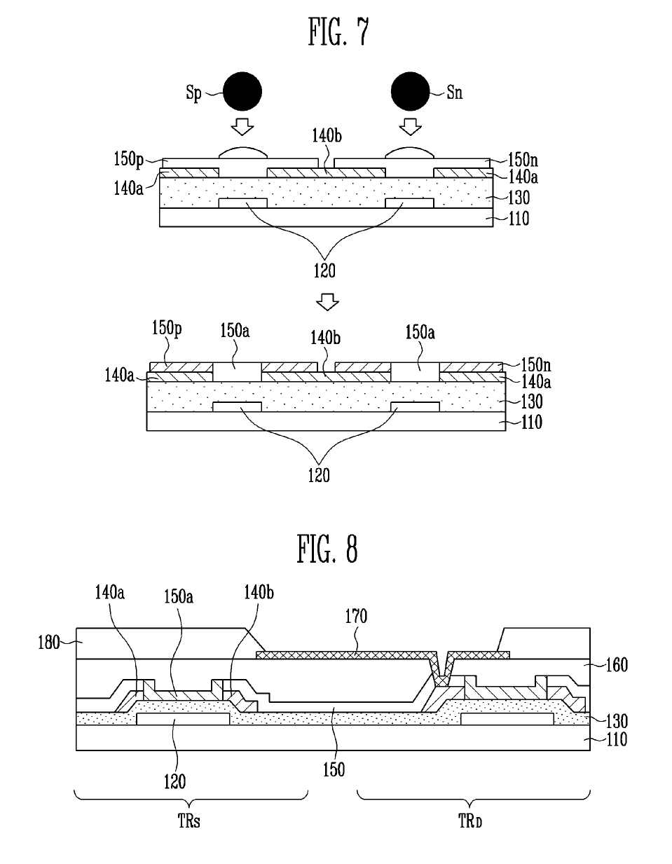

FIG. 8 is a cross-sectional view of an OTFT fabricated according to an exemplary embodiment of the present invention, which is used as each of a switching transistor and a driving transistor of an organic light emitting diode (OLED).

Referring to FIG. 8, each of a switching transistor TRS and a driving transistor TRD of an OLED according to the present invention may include a gate electrode 120, a gate insulating layer 130, a source electrode 140a, a drain electrode 140b, and an organic thin film 150 having a partial region 150a whose crystallinity is improved.

That is, the organic thin film 150 whose crystallinity is partially improved is used as an active layer of each of the switching transistor TRS and the driving transistor TRD of the OLED. As a result, the charge mobility of each of the switching transistor TRS and the driving transistor TRD is improved and crosstalk between devices in each of the switching transistor TRS and the driving transistor TRD is minimized.

In this case, the organic thin film 150 may be formed of one selected from the group consisting of pentacene, tetracene, anthracene, naphthalene, α-6-thiophene, α-4-thiophene, perylene, rubrene, polythiophene, poly(p-phenylene vinylene) (PPV), polyparaphenylene, polyfluorenes (PFs), polythiophenevinylene, polythiophene-heterocyclic aromatic copolymer, oligoacene of naphthalene, oligothiophene of α-5-thiophene, metal phthalocyanine, metal-free phthalocyanine, and derivatives thereof.

A passivation layer 160, an anode electrode 170, and a bank layer 180 may be sequentially formed on the organic thin film 150. The anode electrode 170 may be connected to the source electrode 140a of the driving transistor TRD through a contact hole.

Meanwhile, although it is described above that the organic thin film whose crystallinity is partially improved is used as the active layer of each of the switching transistor TRS and the driving transistor TRD of the OLED, the organic thin film according to the present invention can be also applied to other display devices capable of using an OTFT as a pixel driving device, for example, liquid crystal displays (LCDs), inorganic field-emission displays, and electrophoretic displays.

According to the present invention, an organic thin film formed using a solution deposition process is partially coated with an organic solvent or partially annealed with laser beam irradiation, thereby partially improving the crystallinity of the organic thin film. As a result, the organic thin film whose crystallinity is partially improved can be used as an active layer of an OTFT so that the charge mobility of the OTFT can be increased and crosstalk between devices can be reduced without additionally patterning the organic thin film.

In addition, since the crystallinity of the organic thin film can be partially improved at room temperature by coating with an organic solvent, the present invention can be effectively applied to advanced electronic systems using polymer substrates vulnerable to heat, such as flexible displays and radio frequency Identifications (RFIDs).

In the drawings and specification, there have been disclosed typical exemplary embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A method of partially crystallizing an organic thin film, comprising:
forming the organic thin film using an organic semiconductor material;
changing a predetermined region of the organic thin film into a soft phase by coating the predetermined region of the organic thin film with an organic solvent or irradiating the predetermined region of the organic thin film with laser beams; and
improving the crystallinity of the predetermined region of the organic thin film by drying the soft-phase region of the organic thin film for a predetermined time.

2. The method according to claim 1, wherein the forming the organic thin film comprises bringing the organic semiconductor material into an organic semiconductor solution and depositing the organic semiconductor solution on a substrate.

3. The method according to claim 1, wherein the changing the predetermined region of the organic thin film comprises coating the predetermined region of the organic thin film with the organic solvent using one direct printing technique selected from the group consisting of an inkjet printing technique, a screen printing technique, a gravure printing technique, an offset printing technique, and a flexography technique.

4. The method according to claim 1, wherein in changing the predetermined region of the organic thin film, the organic solvent is one selected from the group consisting of dichlorobenzene (DCB), trichlorobenzene (TCB), and 1-butanol, which evaporate slowly.

5. The method according to claim 1, wherein in improving the crystallinity of the predetermined region, when the soft-phase region of the organic thin film is dried, organic molecules are self-assembled in the predetermined region of the organic thin film.

6. A method of fabricating an organic thin film transistor (OTFT), comprising:
sequentially forming a gate electrode, a gate insulating layer, source and drain electrodes, and an organic thin film on a substrate;
changing a predetermined region of the organic thin film into a soft phase by coating the predetermined region of the organic thin film with an organic solvent or irradiating the predetermined region of the organic thin film with laser beams; and
improving the crystallinity of the predetermined region of the organic thin film by drying the soft-phase region of the organic thin film for a predetermined time.

7. The method according to claim 6, wherein the changing the predetermined region of the organic thin film comprises coating the predetermined region of the organic thin film with the organic solvent using one direct printing technique selected from the group consisting of an inkjet printing technique, a screen printing technique, a gravure printing technique, an offset printing technique, and a flexography technique.

8. The method according to claim 6, wherein in changing the predetermined region of the organic thin film, the organic solvent is one selected from the group consisting of dichlorobenzene (DCB), trichlorobenzene (TCB), and 1-butanol, which evaporates slowly.

9. The method according to claim 6, wherein in improving the crystallinity of the predetermined region, when the soft-phase region of the organic thin film is dried, organic molecules are self-assembled in the predetermined region of the organic thin film.
